(19) United States
(12) Patent Application Publication
(10) Pub. No.: US 2021/0167233 A1
(43) Pub. Date: Jun. 3, 2021

(54) PHOTODIODE AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventors: Juncheng XIAO, Wuhan (CN); Fei AI, Wuhan (CN); Jiyue SONG, Wuhan (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 16/763,374

(22) PCT Filed: Jan. 14, 2020
(86) PCT No.: PCT/CN2020/072018

§ 371 Date: May 12, 2020

(30) Foreign Application Priority Data
Nov. 29, 2019 (CN) 201911203586.0

(51) Int. Cl. H01L 31/0224; H01L 31/0203; H01L 31/18; H01L 31/0216; H01L 31/02

(52) U.S. Cl. CPC H01L 31/022408; H01L 31/0203; H01L 31/02005; H01L 31/02164; H01L 31/18

(57) ABSTRACT

A photodiode and a manufacturing method thereof provided in the present application include a P electrode, an N electrode, and a conductive channel configured to connect the P electrode and the N electrode. The conductive channel includes a first conductive channel pattern, a second conductive channel pattern, and a third conductive channel pattern. The second conductive channel pattern is positioned between the first conductive channel pattern and the third conductive channel pattern. Both the first conductive channel pattern and the third conductive channel pattern are comb-like structures.

### FIELD OF INVENTION

The present invention relates to the field of display, and in particular, to a photodiode and a method of manufacturing the same.

### BACKGROUND OF INVENTION

At present, fingerprint recognition technology has been widely used in small and medium-sized panels, including capacitive, ultrasonic, and optical methods. Compared with capacitive and ultrasonic fingerprint recognition technology, optical fingerprint recognition technology has better stability, stronger antistatic ability, better penetrability, and lower cost. Optical fingerprinting technology uses a principle of refraction and reflection of light. When light irradiates a finger, it is received by a photosensitive sensor after being reflected by the finger. The photosensitive sensor can convert a light signal into an electrical signal for reading. Because fingerprint valley and ridge reflect light differently, reflected light intensities of the valley and ridge received by the photosensitive sensor are different, and thus magnitudes of converted current or voltage are different. Therefore, special points in the fingerprint can be captured to provide specific information.

### TECHNICAL PROBLEM

In recent years, commonly used photosensitive sensors are vertical PIN diodes made of amorphous silicon. For a photosensitive sensor, the greater a photo-generated current, the higher a sensitivity of fingerprint recognition. Factors that affect the photo-generated current of a diode are a width of a depletion layer, an area of a diode structure, and a reflectivity of a diode surface. The wider the width of the depletion layer, the more light energy can be absorbed by an intrinsic layer, and electron-hole pairs can be separated by a built-in electric field, so that the photocurrent is greater, and response is better. However, if the depletion layer is too large, a carrier transit time would be too long, thereby reducing response speed of a device.

Therefore, how to improve the sensitivity of fingerprint recognition by increasing the photo-generated current of the photosensitive sensor under a premise that the response speed of the device is satisfied, is a problem that panel manufacturers in the world are trying to overcome.

### SUMMARY OF INVENTION

The present application provides a photodiode and a preparation method thereof, which can improve the sensitivity of fingerprint recognition by increasing the photo-generated current of a photosensitive sensor under the premise that the response speed of the device is satisfied.

The present application provides a photodiode, including: a P electrode, an N electrode, a conductive channel configured to connect the P electrode and the N electrode, and a light-absorbing layer pattern; wherein the light-absorbing layer pattern is defined on the conductive channel, and the light-absorbing layer pattern exposes a part of the conductive channel.

The conductive channel includes a first conductive channel pattern, a second conductive channel pattern, and a third conductive channel pattern, the second conductive channel pattern is positioned between the first conductive channel pattern and the third conductive channel pattern, the first conductive channel pattern and the third conductive channel pattern are comb-like structures, and the first conductive channel pattern, the second conductive channel pattern, and the third conductive channel pattern mesh with each other.

The first conductive channel pattern includes a first main portion and a plurality of first branch portions, and the plurality of first branch portions are disposed at intervals on a first side of the first main portion. The third conductive channel pattern includes a second main portion and a plurality of second branch portions, and the plurality of second branch portions are disposed at intervals on a second side of the second main portion. The first side and the second side are disposed opposite to each other, and the plurality of first branch portions and the plurality of second branch portions is respectively staggered.

In the photodiode provided in the present application, at least one of the second branch portions is disposed between adjacent ones of the first branch portions.

In the photodiode provided in the present application, when one of the second branch portions is disposed between adjacent ones of the first branch portions, the plurality of first branch portions is disposed at equal intervals on the first main portion, and the plurality of second branch portions is disposed at equal intervals on the second main portion.

In the photodiode provided in the present application, when at least two of the second branch portions are disposed between adjacent ones of the first branch portions, a width of the plurality of first branch portions is greater than a width of the second branch portion. In the photodiode provided in the present application, the first main portion includes a first area and a second area that are interconnected, the second main portion includes a third area and a fourth area that are interconnected, wherein the first area is disposed opposite to the third area, and the second area is disposed opposite to the fourth area. The plurality of first branch portions is disposed on the first area at intervals, and the plurality of second branch portions are disposed at intervals on the third area.

In the photodiode provided in the present application, the P electrode is disposed on the conductive channel and extends along one side of the conductive channel, and the N electrode is disposed on the conductive channel and extends along the other side of the conductive channel.

In the photodiode provided in this application, an insulating layer is disposed on the conductive channel and the light-absorbing layer pattern, and a first via-hole and a second via-hole are formed on the insulating layer; and wherein the P electrode is connected to the conductive channel through the first via-hole, and the N electrode is connected to the conductive channel through the second via-hole.

The present application further provides a photodiode, including a P electrode, an N electrode, and a conductive channel configured to connect the P electrode and the N electrode; wherein the conductive channel includes a first conductive channel pattern, a second conductive channel pattern, and a third conductive channel pattern, the second conductive channel pattern is positioned between the first conductive channel pattern and the third conductive channel pattern, the first conductive channel pattern and the third conductive channel pattern are comb-like structures, and the first conductive channel pattern, the second conductive channel pattern, and the third conductive channel pattern mesh with each other.

In the photodiode provided in the present application, the first conductive channel pattern includes a first main portion and a plurality of first branch portions, and the plurality of first branch portions are disposed at intervals on a first side of the first main portion; the third conductive channel pattern includes a second main portion and a plurality of second branch portions, and the plurality of second branch portions are disposed at intervals on a second side of the second main portion; the first side and the second side are disposed opposite to each other, and the plurality of first branch portions and the plurality of second branch portions each are respectively staggered.

In the photodiode provided in the present application, at least one of the second branch portions is disposed between adjacent ones of the first branch portions.

In the photodiode provided in the present application, when one of the second branch portions is disposed between adjacent ones of the first branch portions, the plurality of first branch portions is disposed at equal intervals on the first main portion, and the plurality of second branch portions is disposed at equal intervals on the second main portion.

In the photodiode provided in the present application, when at least two of the second branch portions are disposed between adjacent ones of the first branch portions, a width of the plurality of first branch portions each is greater than a width of the second branch portion.

In the photodiode provided in the present application, the first main portion includes a first area and a second area that are interconnected, the second main portion includes a third area and a fourth area that are interconnected, wherein the first area is disposed opposite to the third area, and the second area is disposed opposite to the fourth area. The plurality of first branch portions is disposed on the first area at intervals, and the plurality of second branch portions are disposed at intervals on the third area.

In the photodiode provided in the present application, the light-absorbing layer pattern is defined on the conductive channel, and the light-absorbing layer pattern exposes a part of the conductive channel.

In the photodiode provided in the present application, the P electrode is disposed on the conductive channel and extends along one side of the conductive channel, and the N electrode is disposed on the conductive channel and extends along the other side of the conductive channel.

In the photodiode provided in this application, an insulating layer is disposed on the conductive channel and the light-absorbing layer pattern, and a first via-hole and a second via-hole are formed on the insulating layer; and wherein the P electrode is connected to the conductive channel through the first via-hole, and the N electrode is connected to the conductive channel through the second via-hole.

The present application also provides a method of manufacturing a photodiode, including:

Providing a substrate on which a light-shielding layer pattern and a buffer layer are sequentially formed. Forming a conductive channel on the buffer layer, and subjecting the conductive channel to an ion doping treatment to form a first conductive channel pattern, a second conductive channel pattern, and a third conductive channel pattern, wherein the second conductive channel pattern is positioned between the first conductive channel pattern and the third conductive channel pattern, the first conductive channel pattern and the third conductive channel pattern are comb-like structures, and the first conductive channel pattern, the second conductive channel pattern, and the third conductive channel pattern mesh with each other. Forming a P electrode and an N electrode on the conductive channel, wherein the P electrode and the N electrode are configured to connect to the conductive channel.

### BENEFICIAL EFFECT

In the photodiode and the manufacturing method thereof provided by the present application, the conductive channels of the photodiode are configured to comb-like structures that mesh with each other, which increases the junction area of the diode and thereby increases the photo-generated current. In addition, the light-absorbing layer is added to the conductive channel, which can fully absorb the light reflected by the fingerprint to generate more electron-hole pairs, so that the photo-generated current is increased. Therefore, the sensitivity of fingerprint recognition can be improved by increasing the photo-generated current of the photosensitive sensor under the premise that the response speed of the device is satisfied.

### DESCRIPTION OF DRAWINGS

In order to explain the technical solution in this application more clearly, the drawings used in the description of the embodiments will be briefly introduced below. Obviously, the drawings in the description are some embodiments of the present application. For those skilled in the art, other drawings can be obtained based on these drawings without creative efforts.

FIG. 1 is a schematic diagram of a first structure of a photodiode according to an embodiment of the present application.

FIG. 2 is a schematic diagram of a first structure of a conductive channel according to an embodiment of the present application.

FIG. 3 is a schematic diagram of a second structure of a conductive channel according to an embodiment of the present application.

FIG. 4 is a schematic diagram of a third structure of a conductive channel according to an embodiment of the present application.

FIG. 5 is a schematic diagram of a fourth structure of a conductive channel according to an embodiment of the present application.

FIG. 6 is a schematic diagram of a second structure of a photodiode according to an embodiment of the present application.

FIG. 7 is a schematic diagram of a third structure of a photodiode according to an embodiment of the present application.

FIG. 8 is a schematic flowchart of a method of manufacturing a photodiode according to an embodiment of the present application.

FIG. 9 is a schematic flowchart of a sub-process of a method of manufacturing a photodiode according to an embodiment of the present application.

### DETAILED DESCRIPTION OF PREFERRED EMBODIMENTS

The technical solutions in the present application will be clearly and completely described below with reference to the accompanying drawings in the embodiments of the present application. Obviously, the described embodiments are only a part of the embodiments of the present application, and not all the embodiments. Based on the embodiments in the present application, all other embodiments obtained by those skilled in the art without creative effort fall into the scope of protection of the present application.

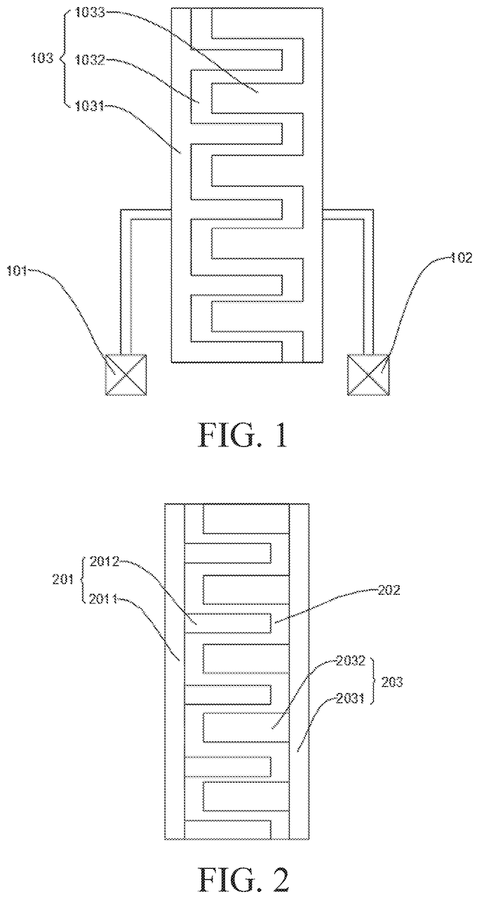

Please refer to FIG. 1, which is a schematic diagram of a first structure of a photodiode according to an embodiment of the present application. As shown in FIG. 1, the photodiode provided in the embodiment of the present application includes a P electrode 101, an N electrode 102, and a conductive channel 103 configured to connect the P electrode 101 and the N electrode 102, wherein the conductive channel 103 includes a first conductive channel pattern 1031, a second conductive channel pattern 1032, and a third conductive channel pattern 1033.

The second conductive channel pattern 1032 is positioned between the first conductive channel pattern 1031 and the third conductive channel pattern 1033, the first conductive channel pattern 1031 and the third conductive channel pattern 1033 are comb-like structures, and the first conductive channel pattern 1031, the second conductive channel pattern 1032, and the third conductive channel pattern 1033 mesh with each other.

It can be understood that the conductive channel patterns of the photodiodes in the prior art are all rectangular designs. The conductive channel of the photodiode provided by the present application adopts a comb-like design and mesh with each other. Compared with the original contact surface of a straight line, the contact surface has many polylines, so that the contact area of the PN junction of the photodiode is increased, and the photo-generated current is improved. Therefore, a technical effect of improving a sensitivity of fingerprint recognition of a photosensitive sensor is achieved.

In one embodiment, a material of the first conductive channel pattern 1031 is boron ion-doped polysilicon, a material of the second conductive channel pattern 1032 is amorphous silicon, and a material of the third conductive channel pattern 1033 is phosphorus ion-doped polysilicon.

Specifically, please refer to FIG. 2, which is a schematic diagram of a first structure of a conductive channel according to an embodiment of the present application. The conductive channel provided in the present application includes a first conductive channel pattern 201, a second conductive channel pattern 202, and a third conductive channel pattern 203, wherein the first conductive channel pattern 201 includes a first main portion 2011 and a plurality of first branch portions 2012. The plurality of first branches 2012 are disposed at intervals on a first side 2013 of the first main portion 2011. The third conductive channel pattern 203 includes a second main portion 2031 and a plurality of second branch portions 2032, and the plurality of second branch portions 2032 are disposed at intervals on a second side 2033 of the second main portion 2031. The first side 2013 and the second side 2033 are disposed opposite to each other, and the plurality of first branch portions 2012 and the plurality of second branch portions 2032 are respectively staggered.

Both the first conductive channel pattern 201 and the third conductive channel pattern 203 are comb-like structures, and the first conductive channel pattern 201, the second conductive channel pattern 202, and the third conductive channel pattern 203 mesh with each other.

In one embodiment, a shape of the first branch portions 2012 and the second branch portions 2032 includes one of a semi-ellipse, a rectangle, or a triangle, wherein when the shape of the first branch portions 2012 and the second branch portions 2032 are rectangular, an area of the PN junction in the photodiode is largest, so as to achieve the best technical effect of improving the sensitivity of fingerprint recognition of the photosensitive sensor. Because difficulties of forming different shapes are different, and the technical effects achieved are different, the specific shape of the first branch portions 2012 and the second branch portions 2032 is determined according to the specific process flow.

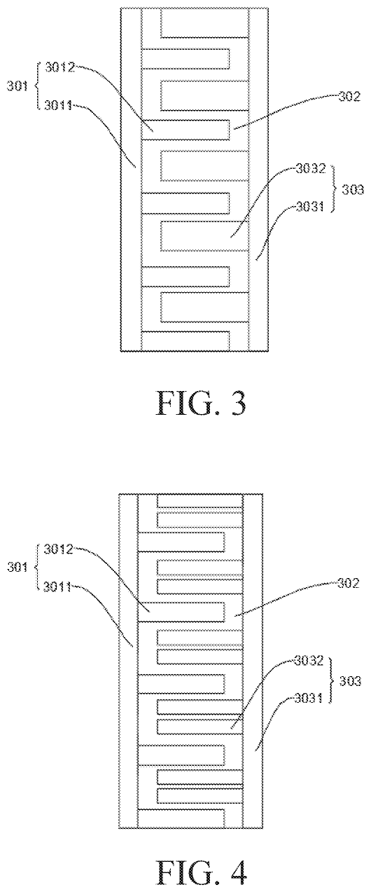

Specifically, please refer to FIG. 3, which is a schematic diagram of a second structure of a conductive channel according to an embodiment of the present application. The conductive channel provided in the present application includes a first conductive channel pattern 301, a second conductive channel pattern 302, and a third conductive channel pattern 303. The first conductive channel pattern 301 includes a first main portion 3011 and a plurality of first branch portions 3012. The plurality of first branch portions 3012 are disposed at intervals on the first side 3013 of the first main portion 3011. The third conductive channel pattern 303 includes a second main portion 3031 and a plurality of second branch portions 3032. The plurality of second branch portions 3032 are disposed at intervals on the second side 3033 of the second main portion 3031. The first side 3013 and the second side 3033 are disposed opposite to each other, and the plurality of first branch portions 3012 and the plurality of second branch portions 3032 are respectively staggered.

Both the first conductive channel pattern 301 and the third conductive channel pattern 303 are comb-like structures. In addition, the first conductive channel pattern 301, the second conductive channel pattern 302, and the third conductive channel pattern 303 mesh with each other.

One of the second branch portions 3032 is disposed between adjacent ones first branch portions 3012, the plurality of first branch portions 3012 are disposed at equal intervals on the first main portion 3011, and the plurality of second branch portions 3032 are disposed at equal intervals on the second main portion 3031.

Further, please refer to FIG. 4, which is a schematic diagram of a third structure of a conductive channel provided by an embodiment of the present application.

The difference between the conductive channel shown in FIG. 4 and the conductive channel shown in FIG. 3 is that in the conductive channel shown in FIG. 4, two of the second branch portions 3032 are provided between the adjacent first branch portions 3012. A thickness of the first branch portions 3012 is greater than that of the second branch portions 3032.

It can be understood that the thickness of the first branch portions 3012 in the conductive channel shown in FIG. 4 is relatively thick, so when the first branch portions 3012 are manufactured, the process is simpler. Compared with FIG. 3, an area of the PN junction in the photodiode is not as large as that in FIG. 3, so the technical effect of improving the sensitivity of the photosensitive sensor fingerprint recognition is not as good as the conductive channel shown in FIG. 3. However, the process of manufacturing the conductive channel shown in FIG. 4 is simpler and less prone to failure, thereby reducing costs.

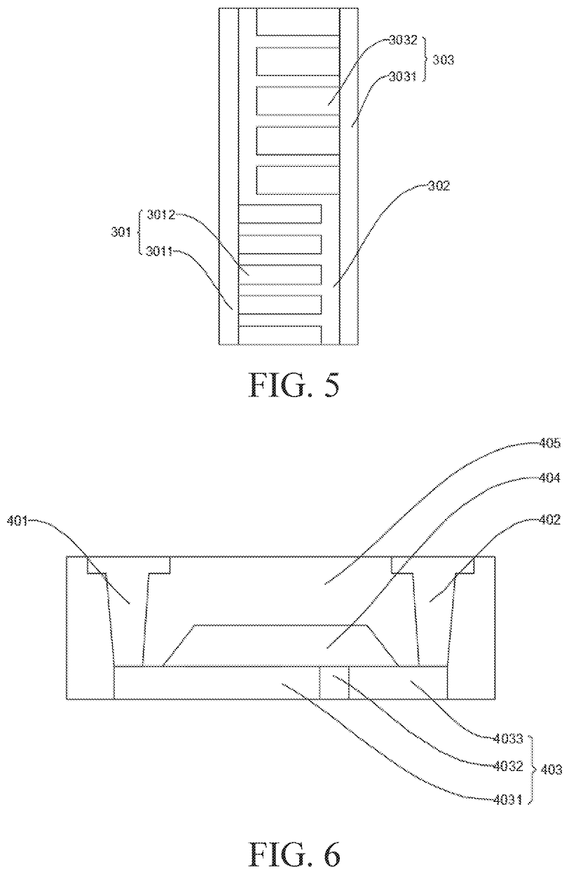

Further, please refer to FIG. 5, which is a schematic diagram of a fourth structure of a conductive channel according to an embodiment of the present application. The difference between the conductive channel shown in FIG. 5 and the conductive channel shown in FIG. 3 is that the first main portion 3011 includes a first region 30111 and a second region 30112 connected to each other. The second main portion 3031 includes a third region 30311 and a fourth region 30312 connected to each other, wherein the first region 30111 and the third region 30311 are disposed opposite to each other, the second region 30112 and the fourth region 30312 are disposed opposite to each other, a plurality of the first branch portions 3012 are disposed at intervals on the first region 30111, and a plurality of the second branch portions 3032 are disposed at intervals on the third region 30311.

It can be understood that the first branch portions 3012 and the second branch portions 3032 shown in FIG. 5 are arranged in different regions. In this way, the first branch portions 3012 and the second branch portions 3032 can be manufactured in different regions, and it is not necessary to manufacture the second branch portions 3032 in the interval between the adjacent first branch portions 3012 after the first branch portions 3012 are manufactured. Therefore, the difficulty of the manufacturing process is reduced, the yield is increased, and the cost is reduced.

In the photodiodes provided in the present application, the conductive channels of the photodiodes are arranged in comb-like structures and mesh with each other, thereby increasing the junction area of the diodes and further increasing the photo-generated current. Therefore, the sensitivity of the fingerprint recognition is improved by increasing the photo-generated current of the photosensitive sensor under the premise that the response speed of the device is satisfied.

Specifically, please refer to FIG. 6, which is a schematic diagram of a second structure of a photodiode according to an embodiment of the present application. As shown in FIG. 6, the photodiode provided in the embodiment of the present application includes a P electrode 401, an N electrode 402, a conductive channel 403 configured to connect the P electrode 401 and the N electrode 402, a light-absorbing layer pattern 404, and an insulating layer 405.

The conductive channel 403 includes a first conductive channel pattern 4031, a second conductive channel pattern 4032, and a third conductive channel pattern 4033, the light-absorbing layer pattern 404 is disposed on the conductive channel 403, and the light-absorbing layer pattern 404 exposes a part of the conductive channel 403. The insulating layer 405 is disposed on the conductive channel 403 and the light-absorbing layer pattern 404, and a first via-hole 4051 and a second via-hole 4052 are formed on the insulating layer 405, wherein the P electrode 401 is connected to the conductive channel 403 through the first via-hole 4051, and the N electrode 402 is connected to the conductive channel 403 through the second via-hole 4052.

It can be understood that a material of the light-absorbing layer pattern 404 is amorphous silicon, and in order to ensure sufficient absorption of light, a thickness of the light-absorbing layer pattern 404 is at least 1000 angstroms.

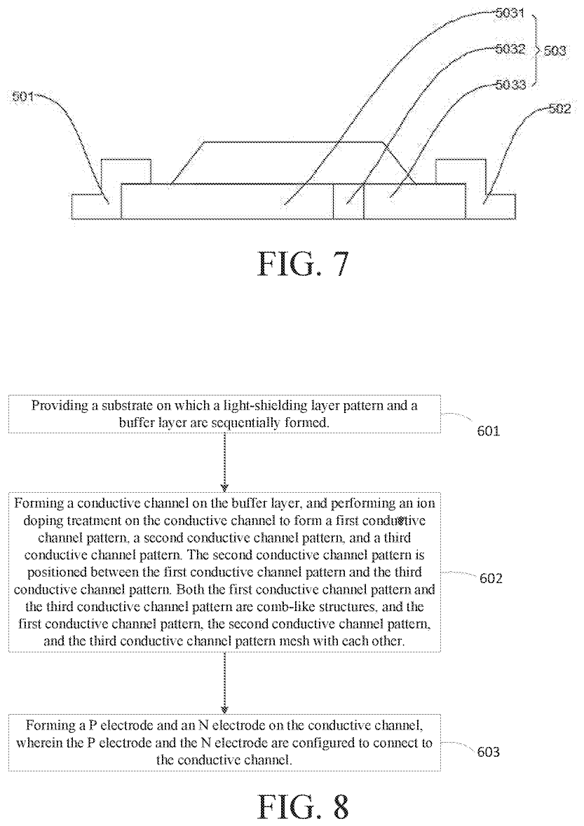

Further, please refer to FIG. 7, which is a schematic diagram of a third structure of a photodiode according to an embodiment of the present application. As shown in FIG. 7, the photodiode provided in the embodiment of the present application includes a P electrode 501, an N electrode 502, a conductive channel 503 configured to connect the P electrode 501 and the N electrode 502, and a light-absorbing layer pattern 404.

The conductive channel 503 includes a first conductive channel pattern 5031, a second conductive channel pattern 5032, and a third conductive channel pattern 5033. The light-absorbing layer pattern 504 is disposed on the conductive channel 503, and the light-absorbing layer pattern 504 exposes a part of the conductive channel 503. The P electrode 501 is disposed on the conductive channel 503 and extends along one side of the conductive channel 503. The N electrode 502 is disposed on the conductive channel 503 and extends along the other side of the conductive channel 503.

In the photodiode and the manufacturing method thereof provided by the present application, by adding a light-absorbing layer on the conductive channel, the light reflected by the fingerprint can be fully absorbed, and more electron-hole pairs can be generated, thereby increasing the photo-generated current. Therefore, the technical problem of improving the sensitivity of fingerprint recognition by increasing the photo-generated current of the photosensitive sensor under the premise that the response speed of the device is satisfied is solved.

Specifically, please refer to FIG. 8, which is a schematic flowchart of a method of manufacturing a photodiode according to an embodiment of the present application. The method includes the following steps: 601, providing a substrate on which a light-shielding layer pattern and a buffer layer are sequentially formed. 602, forming a conductive channel on the buffer layer, and performing an ion doping treatment on the conductive channel to form a first conductive channel pattern, a second conductive channel pattern, and a third conductive channel pattern. The second conductive channel pattern is positioned between the first conductive channel pattern and the third conductive channel pattern. Both the first conductive channel pattern and the third conductive channel pattern are comb-like structures, and the first conductive channel pattern, the second conductive channel pattern, and the third conductive channel pattern mesh with each other. 603, forming a P electrode and an N electrode on the conductive channel, wherein the P electrode and the N electrode are configured to connect to the conductive channel.

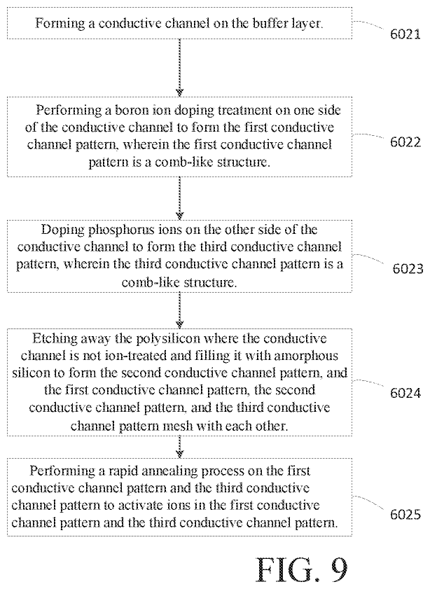

Further, please refer to FIG. 8 and FIG. 9. FIG. 9 is a schematic flowchart of a sub-process of a method of manufacturing a photodiode according to an embodiment of the present application. With reference to FIG. 8 and FIG. 9, process 602 specifically includes: 6021, forming a conductive channel on the buffer layer; 6022, performing a boron ion doping treatment on one side of the conductive channel to form the first conductive channel pattern, wherein the first conductive channel pattern is a comb-like structure; 6023, doping phosphorus ions on the other side of the conductive channel to form the third conductive channel pattern, wherein the third conductive channel pattern is a comb-like structure; 6024, etching away the polysilicon where the conductive channel is not ion-treated and filling it with amorphous silicon to form the second conductive channel pattern, and the first conductive channel pattern, the second conductive channel pattern, and the third conductive channel pattern mesh with each other; and 6025, performing a rapid annealing process on the first conductive channel pattern and the third conductive channel pattern to activate ions in the first conductive channel pattern and the third conductive channel pattern.

It can be understood that the first conductive channel pattern and the third conductive channel pattern are subjected to rapid annealing treatment so that the ions in the first conductive channel pattern and the third conductive channel pattern are activated. Therefore, the contact resistance of the first conductive channel pattern and the third conductive channel pattern with the P electrode and the N electrode can be reduced, thereby the photo-generated current of the photodiode is further increased.

In one embodiment, forming a P electrode on the conductive channel needs to extend along one side of the conductive channel to the buffer layer and cover one side of the conductive channel, and forming an N electrode on the conductive channel needs to extend along the other side of the conductive channel to the buffer layer and cover the other side of the conductive channel. After the P electrode and the N electrode are formed, a light-absorbing layer pattern needs to be formed on the conductive channel, and an insulating layer is provided on the P electrode, the N electrode, the conductive channel, and the light-absorbing layer pattern.

In one embodiment, before forming the P electrode and the N electrode on the conductive channel, it is necessary to form a light-absorbing layer pattern on the conductive channel and provide an insulating layer on the conductive channel and the light-absorbing layer pattern, and then, a first via-hole and a second via-hole are provided on the insulating layer, a P electrode is connected to the conductive channel at the first via-hole, and an N electrode is connected to the conductive channel at the second via-hole.

In the method of manufacturing a photodiode provided by the present application, the conductive channel of the photodiode is configured to comb-like structures that mesh with each other, which increases a junction area of the diode and thereby increases the photo-generated current. In addition, a light-absorbing layer is added to the conductive channel, which can fully absorb the light reflected by the fingerprint to generate more electron-hole pairs, so that the photo-generated current is increased. Therefore, the sensitivity of fingerprint recognition can be improved by increasing the photo-generated current of a photosensitive sensor under the premise that the response speed of the device is satisfied.

The foregoing provides a detailed introduction to the embodiment of the present application. Specific examples are used to explain the principle and embodiments of the present application. The description of the above embodiments is only used to help understand the present application. In addition, for those skilled in the art, according to the idea of the present application, there can be changes in the specific embodiment and the scope of the application. As described above, the content of the specification should not be construed as a limitation on the present application.

What is claimed is:

1. A photodiode, comprising:
a P electrode, an N electrode, a conductive channel configured to connect the P electrode to the N electrode, and a light-absorbing layer pattern;
wherein the light-absorbing layer pattern is defined on the conductive channel, and the light-absorbing layer pattern exposes a part of the conductive channel;
wherein the conductive channel comprises a first conductive channel pattern, a second conductive channel pattern, and a third conductive channel pattern, the second conductive channel pattern is positioned between the first conductive channel pattern and the third conductive channel pattern, the first conductive channel pattern and the third conductive channel pattern are comb-like structures, and the first conductive channel pattern, the second conductive channel pattern, and the third conductive channel pattern mesh with each other; and
wherein the first conductive channel pattern comprises a first main portion and a plurality of first branch portions, and the plurality of first branch portions are disposed at intervals on a first side of the first main portion, the third conductive channel pattern comprises a second main portion and a plurality of second branch portions, and the plurality of second branch portions are disposed at intervals on a second side of the second main portion, the first side and the second side are disposed opposite to each other, and the plurality of first branch portions and the plurality of second branch portions are respectively staggered.

2. The photodiode according to claim 1, wherein at least one of the second branch portions is disposed between adjacent first branch portions.

3. The photodiode according to claim 2, wherein when one of the second branch portions is disposed between the adjacent first branch portions, the plurality of first branch portions are disposed at equal intervals on the first main portion, and the plurality of second branch portions are disposed at equal intervals on the second main portion.

4. The photodiode according to claim 2, wherein when at least two of the second branch portions are disposed between the adjacent first branch portions, a width of the plurality of first branch portions is greater than a width of the second branch portions.

5. The photodiode according to claim 1, wherein the first main portion comprises a first area and a second area that are interconnected, and the second main portion comprises a third area and a fourth area that are interconnected;
wherein the first area is disposed opposite to the third area, and the second area is disposed opposite to the fourth area, the plurality of first branch portions are disposed at intervals on the first area, and the plurality of second branch portions are disposed at intervals on the third area.

6. The photodiode according to claim 1, wherein the P electrode is disposed on the conductive channel and extends along one side of the conductive channel, and the N electrode is disposed on the conductive channel and extends along the other side of the conductive channel.

7. The photodiode according to claim 1, wherein an insulating layer is disposed on the conductive channel and the light-absorbing layer pattern, and a first via-hole and a second via-hole are formed on the insulating layer; and
wherein the P electrode is connected to the conductive channel through the first via-hole, and the N electrode is connected to the conductive channel through the second via-hole.

8. A photodiode, comprising:
a P electrode, an N electrode, and a conductive channel configured to connect the P electrode and the N electrode;
wherein the conductive channel comprises a first conductive channel pattern, a second conductive channel pattern, and a third conductive channel pattern, the second conductive channel pattern is positioned between the first conductive channel pattern and the third conductive channel pattern, the first conductive channel pattern and the third conductive channel pattern are comb-like structures, and the first conductive channel pattern, the second conductive channel pattern, and the third conductive channel pattern mesh with each other.

9. The photodiode according to claim 8, wherein the first conductive channel pattern comprises a first main portion and a plurality of first branch portions, and the plurality of first branch portions are disposed at intervals on a first side of the first main portion, the third conductive channel pattern comprises a second main portion and a plurality of second branch portions, and the plurality of second branch portions are disposed at intervals on a second side of the second main portion, the first side and the second side are disposed opposite to each other, and the plurality of first branch portions and the plurality of second branch portions are respectively staggered.

10. The photodiode according to claim 9, wherein at least one of the second branch portions is disposed between adjacent first branch portions.

11. The photodiode according to claim 10, wherein when one of the second branch portions is disposed between the adjacent first branch portions, the plurality of first branch portions are disposed at equal intervals on the first main portion, and the plurality of second branch portions are disposed at equal intervals on the second main portion.

12. The photodiode according to claim 10, wherein when at least two of the second branch portions are disposed between the adjacent first branch portions, a width of the plurality of first branch portions is greater than a width of the second branch portions.

13. The photodiode according to claim 9, wherein the first main portion comprises a first area and a second area that are interconnected, and the second main portion comprises a third area and a fourth area that are interconnected;
wherein the first area is disposed opposite to the third area, the second area is disposed opposite to the fourth area, the plurality of first branch portions are disposed at intervals on the first area, and the plurality of second branch portions are disposed at intervals on the third area.

14. The photodiode according to claim 8, wherein the light-absorbing layer pattern is defined on the conductive channel and the light-absorbing layer pattern exposes a part of the conductive channel.

15. The photodiode according to claim 14, wherein the P electrode is disposed on the conductive channel and extends along one side of the conductive channel, and the N electrode is disposed on the conductive channel and extends along the other side of the conductive channel.

16. The photodiode according to claim 14, wherein an insulating layer is disposed on the conductive channel and the light-absorbing layer pattern, and a first via-hole and a second via-hole are formed on the insulating layer, and wherein the P electrode is connected to the conductive channel through the first via-hole, and the N electrode is connected to the conductive channel through the second via-hole.

17. A method of manufacturing a photodiode, comprising following steps:
providing a substrate on which a light-shielding layer pattern and a buffer layer are sequentially formed;
forming a conductive channel on the buffer layer, and subjecting the conductive channel to an ion doping treatment to form a first conductive channel pattern, a second conductive channel pattern, and a third conductive channel pattern, wherein the second conductive channel pattern is positioned between the first conductive channel pattern and the third conductive channel pattern, the first conductive channel pattern and the third conductive channel pattern are comb-like structures, and the first conductive channel pattern, the second conductive channel pattern, and the third conductive channel pattern mesh with each other; and
forming a P electrode and an N electrode on the conductive channel, wherein the P electrode and the N electrode are configured to connect to the conductive channel.
